(19) United States
(12) Patent Application Publication
(10) Pub. No.: US 2023/0031955 A1
(43) Pub. Date: Feb. 2, 2023

(54) POST APPLICATION/EXPOSURE TREATMENTS TO IMPROVE DRY DEVELOPMENT PERFORMANCE OF METAL-CONTAINING EUV RESIST

(71) Applicant: Lam Research Corporation, Fremont, CA (US)

(72) Inventors: Jengyi Yu, San Ramon, CA (US); Da Li, Newark, CA (US); Samantha S.H. Tan, Newark, CA (US); Younghee Lee, Pleasanton, CA (US)

(73) Assignee: Lam Research Corporation, Fremont, CA (US)

(21) Appl. No.: 17/758,567

(22) PCT Filed: Jan. 29, 2021
(86) PCT No.: PCT/US2021/015656

§ 371 Date: Jul. 8, 2022

Related U.S. Application Data
(60) Provisional application No. 62/970,020, filed on Feb. 4, 2020.

(51) Int. Cl. G03F 7/16; H01L 21/027; G03F 7/38

(52) U.S. Cl. CPC G03F 7/168; H01L 21/027; G03F 7/38; G03F 7/2004

(57) ABSTRACT

Various embodiments described herein relate to methods, apparatus, and systems for treating metal-containing photoresist to modify material properties of the photoresist. For instance, the techniques herein may involve providing a substrate in a process chamber, where the substrate includes a photoresist layer over a substrate layer, and where the photoresist includes metal, and treating the photoresist to modify material properties of the photoresist such that etch selectivity in a subsequent post-exposure dry development process is increased. In various embodiments, the treatment may involve exposing the substrate to elevated temperatures and/or to a remote plasma. One or more process conditions such as temperature, pressure, ambient gas chemistry, gas flow/ratio, and moisture may be controlled during treatment to tune the material properties as desired.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

This disclosure relates generally to the field of semiconductor processing. In particular aspects, the disclosure is directed to methods and apparatus for processing of EUV photoresists (e.g., EUV-sensitive metal and/or metal oxide-containing resist films) in the context of EUV patterning and EUV patterned film development to form a patterning mask.

### SUMMARY

Various embodiments herein relate to methods, apparatus, and systems for processing a substrate.

In one aspect of the disclosed embodiments, a method of processing a substrate is provided, the method including: providing a substrate in a process chamber, where the substrate includes a substrate layer and photoresist positioned over the substrate layer, and where the photoresist includes metal; and performing a treatment on the photoresist to modify material properties of the photoresist such that etch selectivity in a subsequent post-exposure dry development process is increased.

In certain embodiments, the treatment may result in increased cross-linking in the photoresist. In these or other embodiments, the treatment may involve a thermal process with control of temperature, pressure, ambient gas chemistry, gas flow/ratio, and moisture. In various embodiments, the ambient gas chemistry may include an inert gas selected from the group consisting of nitrogen (N₂), helium, neon, argon, xenon, and combinations thereof. In some such cases, the ambient gas chemistry may be substantially free of reactive gases. In some other cases, the ambient gas chemistry may include a reactive gas species. In some such cases, the reactive gas species may be selected from the group consisting of water, hydrogen (H₂), oxygen (O₂), ozone, hydrogen peroxide, carbon monoxide, carbon dioxide, carbonyl sulfide, sulfur dioxide, chlorine (Cl₂), ammonia, nitrous oxide, nitric oxide, methane, an alcohol, acetyl acetone, formic acid, oxalyl chloride, pyridine, a carboxylic acid, an amine, and combinations thereof.

In various embodiments, the photoresist has been applied to the substrate layer but not yet exposed to patterning radiation. In some such embodiments, the treatment may be a post-application bake (PAB). In these or other embodiments, the treatment may be a post-application remote plasma treatment. In various embodiments, the treatment may increase an exposure radiation sensitivity of the photoresist to thereby achieve a lower dose to size while the substrate is exposed to the patterning radiation, and to achieve a lower line edge roughness after the substrate is exposed to the patterning radiation, as compared to a higher dose to size and a higher line edge roughness that would be achieved without the treatment. In these or other embodiments, the treatment may be conducted at a temperature between about 90 to 250° C. or 90 to 190° C.

In various embodiments, the photoresist has been patterned by partial exposure to patterning radiation resulting in exposed and unexposed portions of the photoresist. In some such embodiments, the treatment is a post-exposure bake (PEB). In these or other embodiments, the treatment may be a post-exposure remote plasma treatment. In various embodiments, the treatment may be conducted at a temperature between about 170 to 250° C. or higher. In these or other embodiments, a composition of both the unexposed and exposed portions of the photoresist may be changed by the treatment to (i) increase an etch rate in a dry development etch gas, (ii) increase a difference in the composition between the unexposed and exposed portions of the photoresist, and/or (iii) increase a difference in one or more material properties between the unexposed and exposed portions of the photoresist.

In various embodiments herein, a temperature of the substrate may be ramped while performing the treatment on the photoresist. In these or other embodiments, the pressure during the treatment may be controlled at atmospheric pressure and below. For instance, the pressure during treatment may be controlled between about 0.1-760 Torr, or between about 0.1-10 Torr. In these or other embodiments, the treatment may involve exposing the photoresist to a remote plasma that generates radicals that react with the photoresist to modify one or more material properties of the photoresist. In some such cases, the radicals may be generated from a gas species selected from the group consisting of water, hydrogen (H₂), oxygen (O₂), ozone, hydrogen peroxide, carbon monoxide, carbon dioxide, carbonyl sulfide, sulfur dioxide, chlorine (Cl₂), ammonia, nitrous oxide, nitric oxide, methane, an alcohol, acetyl acetone, formic acid, oxalyl chloride, pyridine, a carboxylic acid, an amine, and combinations thereof.

In certain embodiments, the treatment may be a thermal treatment performed using a first set of processing conditions and a second set of processing conditions, where the first and second sets of processing conditions vary with respect to at least one of ambient gases or mixtures, temperatures, and/or pressures to thereby modulate material properties of the photoresist and to tune etch selectivity of the photoresist.

In various implementations, the photoresist may be an EUV sensitive film. In these or other embodiments, the treatment may precedes exposing the photoresist to EUV lithography. In some embodiments, the treatment may be performed a second time after exposing the photoresist to EUV lithography. In some embodiments, the treatment occurs after exposing the photoresist to EUV lithography.

In another aspect of the disclosed embodiments, an apparatus for processing a substrate is provided, the apparatus including: a process chamber including a substrate support; a process gas source connected with the process chamber and associated gas flow-control hardware; substrate thermal control apparatus; substrate handling hardware connected with the process chamber; and a controller having a processor, where the processor is at least operatively connected with the gas flow-control hardware, the substrate thermal control apparatus, and the substrate handling hardware, where the controller is configured to cause any one or more of the methods claimed or otherwise described herein.

These and other aspects are described further below with reference to the drawings.

### BRIEF DESCRIPTION OF THE DRAWINGS

FIG. 1 provides a flow chart for a method of treating a substrate according to various embodiments.

FIG. 2 illustrates a substrate over the course of several processing steps where a post-application treatment is used, according to certain embodiments.

FIG. 3 illustrates a substrate over the course of several processing steps where a post-exposure treatment is used, according to various embodiments.

FIG. 4A illustrates a processing chamber in which certain thermally-based steps may take place.

FIG. 4B illustrates a processing chamber in which various steps may take place, including thermally-based steps as well as plasma-based steps.

FIG. 5 depicts a cluster tool having a number of different modules configured to perform different operations, in accordance with certain embodiments herein.

FIGS. 6A-6D depict experimental results showing the improved material contrast and selectivity that can be achieved according to certain embodiments herein.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Patterning of thin films in semiconductor processing is often an important step in the fabrication of semiconductors. Patterning involves lithography. In conventional photolithography, such as 193 nm photolithography, patterns are printed onto a photosensitive photoresist film by exposing the photoresist to photons in selective areas defined by a photomask, thereby causing a chemical reaction in the exposed photoresist and creating a chemical contrast that can be leveraged in the development step to remove certain portions of the photoresist to form the pattern. The patterned and developed photoresist film then can be used as an etch mask to transfer the pattern into underlying films that are composed of metal, oxide, etc.

Advanced technology nodes (as defined by the International Technology Roadmap for Semiconductors) include nodes 22 nm, 16 nm, and beyond. In the 16 nm node, for example, the width of a via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography makes use of EUV resists that are patterned using EUV light to form masks for use in etching underlying layers. EUV resists may be polymer-based chemically amplified resists (CARs) produced by liquid-based spin-on techniques. An alternative to CARs are directly photopatternable metal oxide-containing EUV photoresist films. Such photoresist films may be produced by wet (spin-on) techniques, such as those available from Inpria, Corvallis, Oreg., and described, for example, in US Patent Publications US 2017/0102612 and US 2016/0116839, incorporated by reference herein at least for their disclosure of photopatternable metal oxide-containing films. Such films may be also be produced by dry (vapor deposition) techniques, such as those described in Application PCT/US19/31618, filed May 9, 2019, and titled METHODS FOR MAKING EUV PATTERNABLE HARD MASKS, which is incorporated by reference herein.

These directly photopatternable EUV resists may be composed of or contain high-EUV-absorbance metals and their organometallic oxides/hydroxides and other derivatives. Upon EUV exposure, EUV photons as well as secondary electrons generated can induce chemical reactions, such as beta-H elimination reaction in SnOx-based resist (and other metal oxide-based resists), and provide chemical functionality to facilitate cross-linking and other changes in the resist film. These chemical changes can then be leveraged in the development step to selectively remove the exposed or unexposed area of the resist film and to create an etch mask for pattern transfer.

The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, the disclosure of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate, having exposed hydroxyl groups, is contacted with a hydrocarbyl-substituted tin capping agent to form a hydrocarbyl-terminated SnOx film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. To date, these resists have been developed using a wet (solvent) approach, which requires the wafer to move to a track, where it is exposed to developing solvent, dried and baked. Wet development does not only limit productivity but can also lead to line collapse due to surface tension effects during the evaporation of solvent between fine features.

Dry development techniques have been proposed to overcome these issues by eliminating substrate delamination and interface failures. Dry development has its own challenges, including etch selectivity between unexposed and EUV exposed resist material, which can lead to a higher dose to size requirement for effective resist exposure when compared to wet development. Suboptimal selectivity can also cause photoresist corner rounding due to longer exposures under etching gas, which may increase line critical dimension (CD) variation in the following transfer etch step.

According to various aspects of this disclosure, one or more post treatments to metal and/or metal oxide-based photoresists after deposition (e.g., post-application bake (PAB)) and/or exposure (e.g., post-exposure bake (PEB)) are capable of increasing material property differences between exposed and unexposed photoresist (PR) and therefore decreasing dose to size (DtS), improving PR profile, and improving line edge roughness and line width roughness (LER/LWR) after subsequent dry development. Such processing can involve a thermal process with the control of one or more of temperature, gas ambient, and moisture, resulting in improved dry development performance in processing to follow. In some instances, a remote plasma might be used.

In the case of post-application processing (e.g., PAB), a thermal process with control of one or more of temperature, gas ambient (e.g., using one or more of the gases described herein), pressure, and moisture can be used after deposition and before exposure to change the composition of unexposed metal and/or metal oxide-containing photoresist. The change can increase the EUV sensitivity of the material and thus lower dose to size and line edge roughness can be achieved after exposure and dry development.

In the case of post-exposure processing (e.g., PEB), a thermal process with the control of one or more of temperature, gas atmosphere (e.g., using one or more of the gases described herein), pressure, and moisture can be used to change the composition of both unexposed and exposed photoresist. In some cases, the treatment may preferentially alter the composition and/or material properties of the exposed photoresist compared to the unexposed photoresist, such that the change in composition and/or material property is greater in the exposed photoresist than in the unexposed photoresist. In some other cases, the treatment may preferentially alter the composition/material properties of the unexposed photoresist compared to the exposed photoresist, such that the change in composition and/or material property is greater in the unexposed photoresist than in the exposed photoresist. These preferential interactions may arise due to chemical changes that occur during EUV exposure, for example the loss of alkyl groups within the photoresist. The changes that occur during the treatment can increase the difference in composition/material properties between the unexposed and exposed photoresist, thereby enhancing the difference in etch rate between the unexposed and exposed photoresist. A higher etch selectivity (e.g., during dry development of the pattern in the photoresist) can thereby be achieved. Due to the improved selectivity, a squarer PR profile can be obtained with improved surface roughness, and/or less photoresist residual/scum.

In either case, in alternative implementations, the thermal process could be replaced by or supplemented with a remote plasma process. The remote plasma process may act to increase reactive species, thereby lowering the energy barrier for a desired reaction and increasing productivity. Remote plasma can generate more reactive radicals and therefore lower the reaction temperature/time for the treatment (e.g., as compared to treatments that rely solely on thermal energy), leading to increased productivity.

Accordingly, one or multiple processes may be applied to modify photoresist itself to increase dry development selectivity. This thermal and/or radical modification can increase the contrast between unexposed and exposed material and thus increase the selectivity of the subsequent dry development step. The resulting difference between the material properties of unexposed and exposed material can be tuned by adjusting one or more process conditions including temperature, gas flow, moisture, pressure, and/or RF power. The large process latitude enabled by dry development, which is not limited by material solubility in a wet developer solvent, allows more aggressive conditions to be applied during the treatment, further enhancing the material contrast that can be achieved. The resulting high material contrast feeds back a wider process window for dry development and thus enables increased productivity, lower cost, and better defectivity performance.

A substantial limitation of wet-developed resist films is limited temperature bakes. Wet development relies on differences in material solubility between exposed and unexposed regions of the photoresist. Heating the photoresist to elevated temperatures can greatly increase the degree of cross-linking in both exposed and unexposed regions of a metal-containing PR film. If the photoresist is heated to a temperature of about 220° C. or higher, both the exposed and unexposed regions of the photoresist become insoluble in the wet development solvents, so that the photoresist film can no longer by reliably developed using wet development techniques.

By contrast, for dry-developed resist films in which the dry etch rate difference (i.e., selectivity) between the exposed and unexposed regions of the PR is relied upon for removal of just the exposed or unexposed portion of the resist, the treatment temperature in a PAB or PEB can be varied across a much broader window, since the limitations that apply to solubility in a wet development solvent do not apply to dry etching techniques. As such, in the case of dry development, the treatment process may be tuned/optimized over a relatively wide temperature range. For example, the treatment temperature may range from about 90 to 250° C., such as 90 to 190° C., for a PAB, and from about 170 to 250° C. or more for a PEB. Decreased etch rate and greater etch selectivity have been found to occur with higher treatment temperatures in the noted ranges.

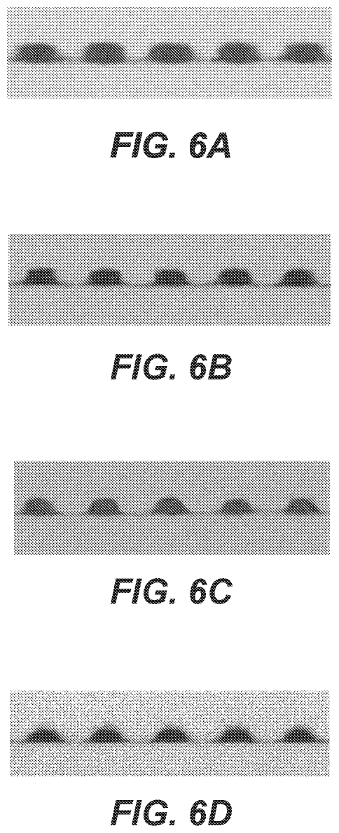

FIGS. 6A-6D depict experimental results showing the improved material contrast and selectivity between unexposed and exposed portions of a photoresist layer that can be achieved by controlling temperature during a PEB. In each example, the substrate was exposed to a PEB in which the temperature of the substrate was controlled (e.g., by controlling the substrate support temperature). Afterwards, the photoresist layer on each substrate was developed using dry techniques to form a series of photoresist features on the substrate. In FIG. 6A, the temperature was controlled at about 235° C. In FIG. 6B, the temperature was controlled at about 220° C. In FIG. 6C, the temperature was controlled at about 205° C. In FIG. 6D, the temperature was controlled at about 190° C. At lower treatment temperatures, the photoresist profile showed significant tapering/rounded features. By contrast, at higher treatment temperatures, the photoresist profile is substantially improved, with the features being much less tapered/round, and much more square. The higher PEB temperatures provide greater material contrast between exposed and unexposed portions of the photoresist, thereby providing higher selectivity when the photoresist is developed. Further, the substrates treated with higher PEB temperatures show higher critical dimensions of the lines after development, which corresponds to a lower dose to size. In other words, the higher treatment temperatures can be used to achieve a desired critical dimension at a lower dose of EUV radiation than would be required to achieve the same critical dimension when the substrate is treated at lower temperatures (or not treated at all). As mentioned above, dry development techniques were used after the PEB treatments. In many cases, wet development techniques are not able to develop a photoresist layer that has been treated with a PEB at high temperatures, e.g., >180° C., for the reasons discussed above.

In particular embodiments, the PAB and/or PEB treatments may be conducted with gas ambient flow in the range of 100-10,000 sccm. In these or other embodiments, the moisture content in the ambient environment may be controlled between about a few percent up to 100% (e.g., in some cases between about 20%-50%). In these or other embodiments, a pressure during treatment may be controlled, for example at or below atmospheric pressure (e.g., using a vacuum to achieve sub-atmospheric pressures). In some cases, the pressure during treatment may be between about 0.1-760 Torr, for example between about 0.1-10 Torr, or between about 0.1-1 Torr in some cases. In these or other embodiments, a duration of the treatment may be controlled between about 1 to 15 minutes, for example between about 2-5 minutes, or about 2 minutes.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity (e.g., a dry etch selectivity of up to 100 in exposed vs. unexposed regions of the photoresist) can be obtained than would be possible in a wet development context. Remote plasma-based treatments may result in the same or similar benefits.

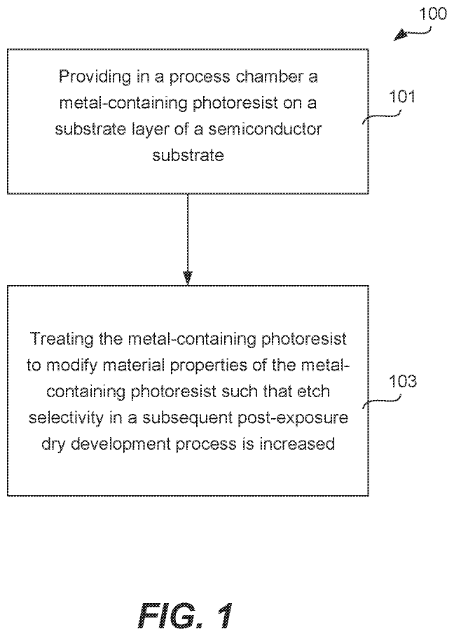

FIG. 1 depicts a process flow for one aspect of this disclosure, a method of processing a semiconductor substrate. The method 100 involves, at 101, providing in a process chamber a metal-containing photoresist on a substrate layer of a semiconductor substrate. The substrate may be, for example, a partially fabricated semiconductor device film stack fabricated in any suitable way. At 103, the metal-containing photoresist is treated to modify material properties of the metal-containing photoresist such that etch selectivity in a subsequent post-exposure dry development process is increased. For example, the treatment may result in increased cross-linking in the metal-containing photoresist.

In some embodiments, the treatment may involve a thermal process with control of temperature, gas ambient, and/or moisture. The gas ambient may include a reactive gas species such as air, water (H₂O), hydrogen (H₂), oxygen (O₂), ozone (O₃), hydrogen peroxide (H₂O₂), carbon monoxide (CO), carbon dioxide (CO₂), carbonyl sulfide (COS), sulfur dioxide (SO₂), chlorine (Cl₂), ammonia (NH₃), nitrous oxide (N₂O), nitric oxide (NO), methane (CH₄), methylamine (CH₃NH₂), dimethylamine ((CH₃)₂NH), trimethylamine (N(CH₃)₃), ethylamine (CH₃CH₂NH₂), diethylamine ((CH₃CH₂)₂NH), triethylamine (N(CH₂CH₃)₃), pyridine (C₅H₅N), alcohols (CₙH₂ₙ₊₁OH, including but not limited to methanol, ethanol, propanol, and butanol), acetyl acetone (CH₃COCH₂COCH₃), formic acid (HCOOH), oxalyl chloride ((COCl₂), carboxylic acids (CₙH₂ₙ₊₁COOH), and other small molecule amines (NR¹R²R³, where each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof), etc. Substituted forms of any of these reactive gases may also be used. In some cases, the substrate may be exposed to two or more reactive gases during a treatment operation.

In embodiments where a reactive gas is used to treat the photoresist, the reactive gas may interact with the photoresist via oxidation, coordination, or acid/base chemistry. In various embodiments, the gas ambient may include an inert gas such as N₂, Ar, He, Ne, Kr, Xe, etc. In some cases, the inert gas may be provided together with one or more of the reactive gases listed above. In other cases, the gas ambient may be inert or substantially inert. For instance, the gas ambient may be free or substantially free of reactive gases. As used herein, a gas atmosphere may be considered substantially free of reactive gases if such gases are only present at trace amounts. In various cases where an inert atmosphere is used, the inert atmosphere may increase the contrast in composition and/or material properties by reducing over oxidation in relevant areas of the photoresist. For instance, in some cases where the photoresist is treated thermally in an inert atmosphere after exposing the photoresist to patterning radiation, the inert atmosphere promotes an increase in material contrast (e.g., composition and/or material properties) by reducing over oxidation present on unexposed areas of the photoresist.

Any of the embodiments described herein may include a reduction step, which may operate to reduce oxidized or overoxidized areas of the photoresist. Such a reduction step may be particularly useful after a step that oxidizes the photoresist (or portions thereof). In various embodiments, the reduction step may involve exposing the substrate to a reducing atmosphere or an inert atmosphere. In some cases, the reduction step may involve heating the substrate and/or exposing the substrate to plasma. The plasma may be generated from inert gas and/or reducing gas.

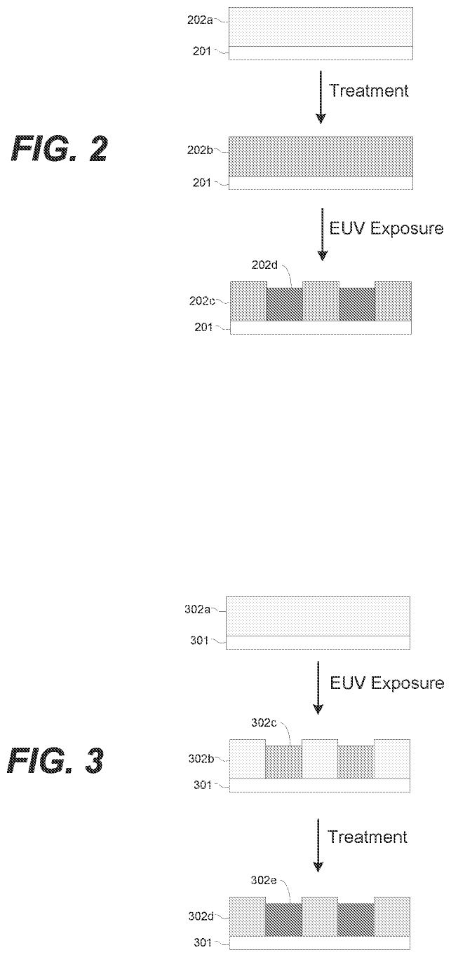

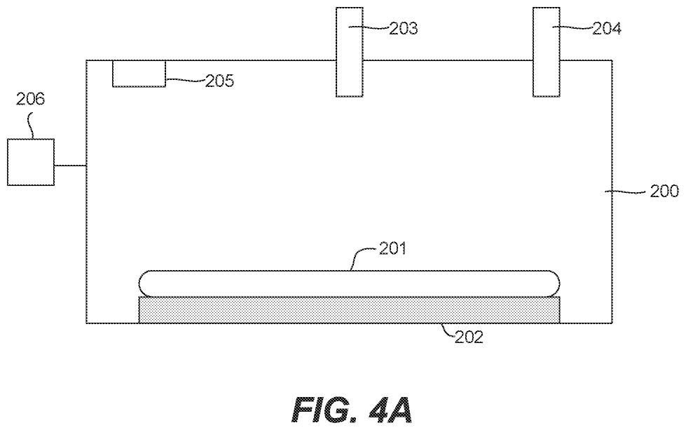

In various embodiments, as depicted in FIG. 2, the treatment may be applied after the photoresist 202a has been applied to the substrate 201, before the photoresist 202a is exposed to patterning radiation. For instance, in one example where the treatment is a thermal treatment, the treatment may be referred to as a post-application bake (PAB). The treatment alters the photoresist 202a to form a modified version of the photoresist 202b. As compared to the photoresist 202a prior to treatment, the modified version of the photoresist 202b exhibits improved properties. For instance, the modified version of the photoresist 202b may be more sensitive to EUV radiation than the unmodified version of the photoresist 202a. As a result of this increased EUV sensitivity, the modified version of the photoresist may exhibit lower dose to size during EUV exposure, and may provide lower line edge roughness after development. The treatment may also be provided at a different time. In various embodiments, as depicted in FIG. 3, the treatment may be applied after the photoresist 302a has been deposited and has been patterned by partial exposure to radiation (e.g., EUV), such that the substrate being treated includes both exposed portions 302c and unexposed portions 302b of the EUV photoresist. For instance, in one example where the treatment is a thermal treatment, the treatment may be referred to as a post-exposure bake (PEB). The treatment may modify both the exposed portions 302c and the unexposed portions 302b of the EUV photoresist, thereby forming a modified version of the exposed portion 302e and a modified version of the unexposed portion 302d. The modifications produced by the treatment may increase the etch rate of the photoresist material in a dry development etch gas. Alternatively or in addition, the modifications produced by the treatment may increase the difference in the composition/material properties between the unexposed portions and exposed portions of the photoresist. In other words, the difference between the composition/material properties when comparing (1) the modified version of the unexposed portion 302d of the photoresist after the treatment and (2) the modified version of the exposed portion 302e of the photoresist after the treatment, is more substantial than the difference between the composition/material properties when comparing (1) the unexposed portions 302b of the photoresist prior to treatment and (2) the exposed portions 302c of the photoresist prior to treatment.

Additionally, the ramping rate of the bake temperature in either PAB or PEB treatments is another useful process parameter that can be manipulated to fine-tune the cross-linking/etch selectivity results. The PAB and PEB thermal process can be done in either a single operation or in multiple operations. Where multiple operations are used, different process conditions may be provided during the individual operations. Example processing conditions that may vary between individual operations include, but are not limited to, the identity and concentration of ambient gases or mixtures proximate the substrate, moisture level, temperatures, pressures, etc. These processing conditions may be controlled to modulate the PR properties and therefore to tune different etch selectivity.

In an alternate embodiment, either or both of the post-application and past-exposure treatments may involve a remote plasma process, together with or instead of thermal processing, to generate radicals to react with the metal-containing photoresist to thereby modify its material properties. With reference to FIG. 2, in some embodiments the remote plasma treatment process occurs after the photoresist 202a is deposited and before it is exposed to EUV radiation. In this case, the treatment may be referred to as a post-application plasma treatment. With reference to FIG. 3, in some embodiments the remote plasma treatment process occurs after the photoresist 302a is deposited and exposed to EUV radiation to form exposed portions 302c and unexposed portions 302b. In this case, the treatment may be referred to as a post-exposure plasma treatment.

In implementations where a remote plasma is used to treat the photoresist, the radicals may be generated from the same or different gas species described herein with respect to the thermal treatment.

In some embodiments, multiple treatments may be used. For example, a first treatment may occur after photoresist deposition and prior to EUV exposure (as shown in FIG. 2), and a second treatment may occur after EUV exposure and prior to development (as shown in FIG. 3). One or more of the processing conditions may be controlled as described herein during the first treatment and/or during the second treatment.

### Apparatus

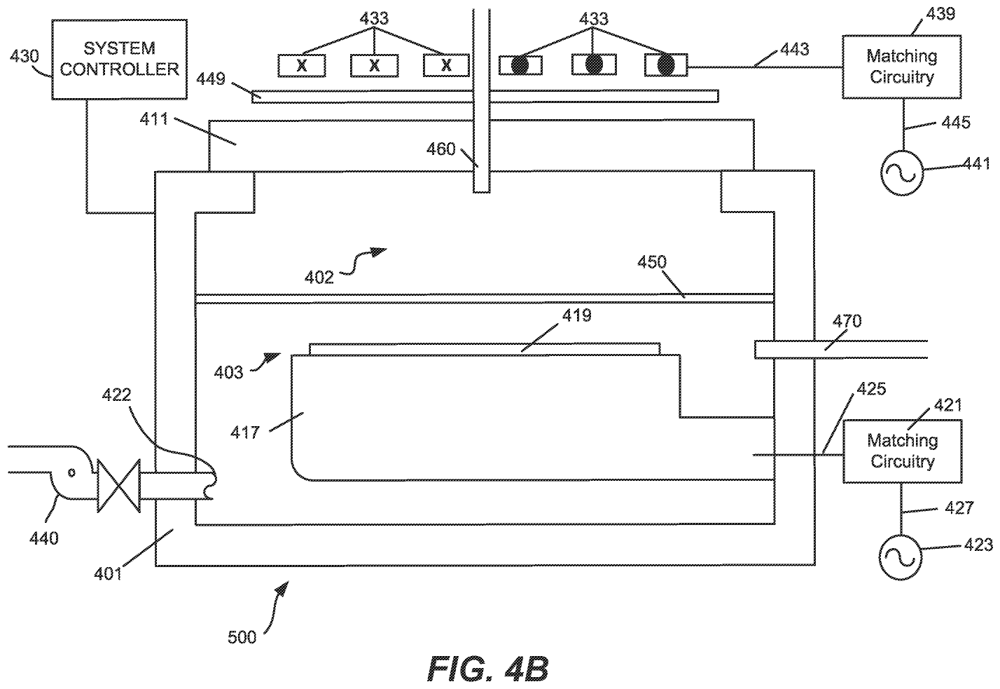

FIGS. 4A and 4B depict schematic illustrations of different embodiments of process stations that may be used to perform the treatments described herein. The process station 480 shown in FIG. 4A may be used for thermal-based treatments such as a post-application bake or a post-exposure bake. The process station 400 shown in FIG. 4B may be used for thermal-based treatments, remote plasma treatments, or both. These treatments can include post-application treatments as well as post-exposure treatments. The process stations shown in FIGS. 4A and 4B may also be used for other processes described herein. For steps where plasma is required, the process station 400 of FIG. 4B may be used. For steps where plasma is not required, either the process station 400 of FIG. 4B or the process station 480 of FIG. 4A may be used.

FIG. 4A presents a simplified view of a processing chamber 480 according to one embodiment. In this example, the processing chamber 480 is a closed chamber having a controllable atmosphere. The substrate 481 may be positioned on substrate support 482, which may also heat and/or cool the substrate. Alternative or additional heating and cooling elements may be provided in some cases. Processing gases enter the processing chamber 480 through inlet 483. Materials are removed from the processing chamber 480 through outlet 484, which may be connected to a vacuum source (not shown). Operation of the processing chamber 480 may be controlled by a controller 486, which is further discussed below. Further, a sensor 485 may be provided, for example to monitor the temperature and/or the composition of the atmosphere in the processing chamber 480. Readings from sensor 485 may be used by controller 486 in an active feedback loop. In various implementations, processing chamber 480 may be modified by including a remote plasma chamber (not shown) in fluidic communication with processing chamber 480. In such cases, plasma may be generated in the remote plasma chamber before the plasma is delivered to the processing chamber 480.

The chamber in which the treatment takes place may be configured in a number of ways. In some embodiments, the chamber is the same chamber used to deposit the photoresist, and/or the same chamber used to expose the photoresist to EUV radiation, and/or the same chamber used to develop the photoresist. In some embodiments, the chamber is a dedicated bake or remote plasma treatment chamber that is not used for other processes such as deposition, etching, EUV exposure, or photoresist development. The chamber may be a standalone chamber, or it may be integrated into a larger processing tool such as the deposition tool used to deposit the photoresist, the EUV exposure tool used to expose the photoresist to EUV radiation, and/or the development tool used to develop the photoresist. The chamber used for treating the photoresist may be combined with any one or more of these tools, for example in a cluster tool, as desired for a particular application. In some cases, the chamber may be provided in a common low pressure process tool environment that provides a low pressure for multiple chambers.

FIG. 4B schematically shows a cross-sectional view of an inductively coupled plasma apparatus 400 appropriate for implementing certain embodiments or aspects of embodiments such as vapor (dry) deposition, thermal treatment as described herein, plasma treatment as described herein, dry development and/or etch, an example of which is a Kiyo® reactor, produced by Lam Research Corp. of Fremont, Calif. In other embodiments, other tools or tool types having the functionality to conduct one or more operations of the dry deposition, treatment (thermal or remote plasma), development and/or etch processes described herein may be used for implementation.

The inductively coupled plasma apparatus 400 includes an overall process chamber 424 structurally defined by chamber walls 401 and a window 411. The chamber walls 401 may be fabricated from stainless steel or aluminum. The window 411 may be fabricated from quartz or other dielectric material. An optional internal plasma grid 450 divides the overall process chamber into an upper sub-chamber 402 and a lower sub chamber 403. In certain embodiments, plasma grid 450 may be removed, thereby utilizing a chamber space made of sub chambers 402 and 403. In places where plasma grid 450 is present, it may be used to shield the substrate from the plasma directly generated in the upper sub-chamber 402, such that the substrate is processed with a remote plasma in the lower sub-chamber 403. In this example, the plasma present in the lower sub-chamber 403 may be considered a remote plasma because it is first generated at a location (e.g., the upper sub-chamber 402) that is upstream from where the substrate is treated with the plasma (e.g., the lower sub-chamber 403).

A chuck 417 is positioned within the lower sub-chamber 403 near the bottom inner surface. The chuck 417 is configured to receive and hold a semiconductor wafer 419 upon which the etching and deposition processes are performed. The chuck 417 can be an electrostatic chuck for supporting the wafer 419 when present. In some embodiments, an edge ring (not shown) surrounds chuck 417 and has an upper surface that is approximately planar with a top surface of the wafer 419, when present over chuck 417. The chuck 417 also includes electrostatic electrodes for chucking and dechucking the wafer 419. A filter and DC clamp power supply (not shown) may be provided for this purpose. Other control systems for lifting the wafer 419 off the chuck 417 can also be provided. The chuck 417 can be electrically charged using an RF power supply 423. The RF power supply 423 is connected to matching circuitry 421 through a connection 427. The matching circuitry 421 is connected to the chuck 417 through a connection 425. In this manner, the RF power supply 423 is connected to the chuck 417. In various embodiments, a bias power of the electrostatic chuck may be set at about 50V or may be set at a different bias power depending on the process performed in accordance with disclosed embodiments. For example, the bias power may be between about 20 Vb and about 100 V, or between about 30 V and about 150 V.

Elements for plasma generation include a coil 433 positioned above window 411. In some embodiments, a coil is not used. In some such embodiments, an alternative mechanism for generating a plasma may be provided, for instance for providing a capacitively coupled plasma, a microwave plasma, etc. In cases where an inductively coupled plasma is used, the coil 433 is fabricated from an electrically conductive material and includes at least one complete turn. The example of a coil 433 shown in FIG. 4B includes three turns. The cross sections of coil 433 are shown with symbols, and coils having an “X” extend rotationally into the page, while coils having a “●” extend rotationally out of the page. Elements for plasma generation also include an RF power supply 441 configured to supply RF power to the coil 433. In general, the RF power supply 441 is connected to matching circuitry 439 through a connection 445. The matching circuitry 439 is connected to the coil 433 through a connection 443. In this manner, the RF power supply 441 is connected to the coil 433.

An optional Faraday shield 449a is positioned between the coil 433 and the window 411. The Faraday shield 449a may be maintained in a spaced apart relationship relative to the coil 433. In some embodiments, the Faraday shield 449a is disposed immediately above the window 411. In some embodiments, the Faraday shield 449b is between the window 411 and the chuck 417. In some embodiments, the Faraday shield 449b is not maintained in a spaced apart relationship relative to the coil 433. For example, the Faraday shield 449b may be directly below the window 411 without a gap. The coil 433, the Faraday shield 449a, and the window 411 are each configured to be substantially parallel to one another. The Faraday shield 449amay prevent metal or other species from depositing on the window 411 of the process chamber 424.

Process gases may be flowed into the process chamber through one or more main gas flow inlets 460 positioned in the upper sub-chamber 402 and/or through one or more side gas flow inlets 470. Likewise, though not explicitly shown, similar gas flow inlets may be used to supply process gases to a capacitively coupled plasma processing chamber. A vacuum pump, e.g., a one or two stage mechanical dry pump and/or turbomolecular pump 440, may be used to draw process gases out of the process chamber 424 and to maintain a pressure within the process chamber 424. For example, the vacuum pump may be used to evacuate the overall process chamber 424 or the lower sub-chamber 403 during a purge operation. A valve-controlled conduit may be used to fluidically connect the vacuum pump to the process chamber 424 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 400, one or more process gases may be supplied through the gas flow inlets 460 and/or 470. In certain embodiments, process gas may be supplied only through the main gas flow inlet 460, or only through the side gas flow inlet 470. In some cases, the gas flow inlets shown in the figure may be replaced by more complex gas flow inlets, one or more showerheads, for example. The Faraday shield 449a and/or optional grid 450 may include internal channels and holes that allow delivery of process gases to the process chamber 424. Either or both of Faraday shield 449a and optional grid 450 may serve as a showerhead for delivery of process gases. In some embodiments, a liquid vaporization and delivery system may be situated upstream of the process chamber 424, such that once a liquid reactant or precursor is vaporized, the vaporized reactant or precursor is introduced into the process chamber 424 via a gas flow inlet 460 and/or 470.

In some embodiments, a remote plasma generation unit may be provided upstream of the process chamber 424, and radicals formed by the remote plasma may be provided to the process chamber via a gas flow inlet 460 and/or 470.

Radio frequency power is supplied from the RF power supply 441 to the coil 433 to cause an RF current to flow through the coil 433. The RF current flowing through the coil 433 generates an electromagnetic field about the coil 433. The electromagnetic field generates an inductive current within the upper sub-chamber 402. The physical and chemical interactions of various generated ions and radicals with the wafer 419 etch features of and selectively deposit layers on the wafer 419.

If the plasma grid 450 is used such that there is both an upper sub-chamber 402 and a lower sub-chamber 403, the inductive current acts on the gas present in the upper sub-chamber 402 to generate an electron-ion plasma in the upper sub-chamber 402. The optional internal plasma grid 450 limits the amount of hot electrons in the lower sub-chamber 403. In some embodiments, the apparatus 400 is designed and operated such that the plasma present in the lower sub-chamber 403 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 403 through port 422. The chuck 417 disclosed herein may operate at elevated temperatures ranging between about 10° C. and about 250° C. or more. The temperature will depend on the process operation and specific recipe.

Apparatus 400 may be coupled to facilities (not shown) when installed in a clean room or a fabrication facility. Facilities include plumbing that provide processing gases, vacuum, temperature control, and environmental particle control. These facilities are coupled to apparatus 400, when installed in the target fabrication facility. Additionally, apparatus 400 may be coupled to a transfer chamber that allows robotics to transfer semiconductor wafers into and out of apparatus 400 using typical automation.

In some embodiments, a system controller 430 (which may include one or more physical or logical controllers) controls some or all of the operations of a process chamber 424. The system controller 430 may include one or more memory devices and one or more processors. In some embodiments, the apparatus 400 includes a switching system for controlling flow rates and durations when disclosed embodiments are performed. In some embodiments, the apparatus 400 may have a switching time of up to about 500 ms, or up to about 750 ms. Switching time may depend on the flow chemistry, recipe chosen, reactor architecture, and other factors.

In some implementations, the system controller 430 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 430, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 430 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 430, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 430 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 430 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (e.g., PECVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

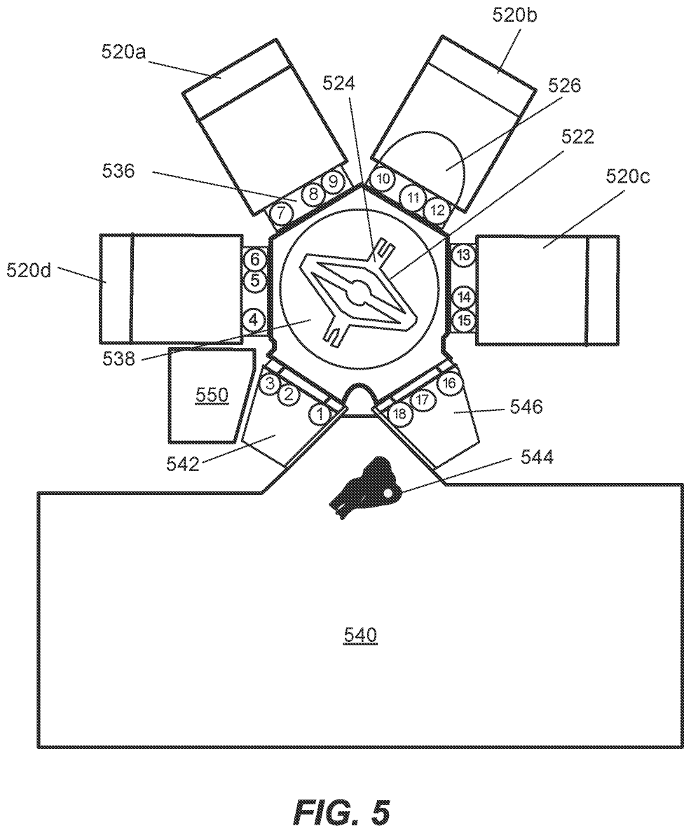

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 5 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 5 depicts a semiconductor process cluster tool architecture with vacuum-integrated deposition and patterning modules suitable for implementation of the embodiments described herein. Such a cluster process tool architecture can include PR and underlayer deposition modules, resist exposure (EUV scanner) modules, and/or resist dry development and etch modules, as described herein. In some embodiments, one or more hardware parameters of the process station including those discussed in detail herein may be adjusted programmatically by one or more computer controllers.

In some embodiments, certain of the processing functions can be performed consecutively in the same module, for example resist film vapor deposition, treatment, exposure and/or dry development and etch. And embodiments of this disclosure are directed to apparatus for processing a substrate, the apparatus having a process chamber comprising a substrate support, a process gas source connected with the process chamber and associated flow-control hardware, thermal control hardware, substrate handling hardware connected with the process chamber, and a controller having a processor and a memory. In some implementations, the processer and the memory are communicatively connected with one another, the processor is at least operatively connected with the flow-control and substrate handling hardware, and the memory stores computer-executable instructions for conducting the operations in the methods of making a pattering structure described herein.

As noted above, FIG. 5 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster. The treatment steps described herein may be performed in any one or more of these modules, or in a separate module dedicated to such treatments.

A vacuum transport module (VTM) 538 interfaces with four processing modules 520a-520d, which may be individually optimized to perform various fabrication processes. By way of example, processing modules 520a-520d may be implemented to perform deposition, evaporation, thermal and/or plasma treatment, electroless deposition, dry development, etch, strip, and/or other semiconductor processes. For example, module 520a may be an ALD reactor that may be operated to perform non-plasma, thermal atomic layer depositions to form metal-containing photoresist or other materials described herein. In one example, module 520a is a Vector® tool, available from Lam Research Corporation of Fremont, Calif. In these or other embodiments, module 520b may be a plasma enhanced chemical vapor deposition (PECVD) tool, such as the Lam Vector®. It should be understood that the figure is not necessarily drawn to scale.

Airlocks 542 and 546, also known as a loadlocks or transfer modules, interface with the VTM 538 and a patterning module 540. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUV lithography also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUV lithography scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 5 but without the integrated patterning module.

Airlock 542 may be an “outgoing” loadlock, referring to the transfer of a substrate out from the VTM 538 serving a deposition module 520a to the patterning module 540, and airlock 546 may be an “ingoing” loadlock, referring to the transfer of a substrate from the patterning module 540 back in to the VTM 538. The ingoing loadlock 546 may also provide an interface to the exterior of the tool for access and egress of substrates. Each process module has a facet that interfaces the module to VTM 538. For example, deposition process module 520a has facet 536. Inside each facet, sensors, for example, sensors 1-18 as shown, are used to detect the passing of wafer 526 when moved between respective stations. Patterning module 540 and airlocks 542 and 546 may be similarly equipped with additional facets and sensors, not shown.

Main VTM robot 522 transfers wafer 526 between modules, including airlocks 542 and 546. In one embodiment, robot 522 has one arm, and in another embodiment, robot 522 has two arms, where each arm has an end effector 524 to pick wafers such as wafer 526 for transport. Front-end robot 544, in is used to transfer wafers 526 from outgoing airlock 542 into the patterning module 540, from the patterning module 540 into ingoing airlock 546. Front-end robot 544 may also transport wafers 526 between the ingoing loadlock and the exterior of the tool for access and egress of substrates. Because ingoing airlock module 546 has the ability to match the environment between atmospheric and vacuum, the wafer 526 is able to move between the two pressure environments without being damaged.

It should be noted that a EUV lithography tool typically operates at a higher vacuum (e.g., lower pressure) than a deposition tool. If this is the case, it is desirable to increase the vacuum environment of the substrate (e.g., apply greater vacuum such that the substrate is exposed to lower pressure) during the transfer between the deposition tool and the EUV lithography tool to allow the substrate to degas prior to entry into the EUV lithography tool. Outgoing airlock 542 may provide this function by holding the transferred wafers at a lower pressure, no higher than the pressure in the patterning module 540, for a period of time and exhausting any off-gassing, so that the optics of the patterning tool 540 are not contaminated by off-gassing from the substrate. A suitable pressure for the outgoing, off-gassing airlock is no more than about 1E-8 Torr.

In some embodiments, a system controller 550 (which may include one or more physical or logical controllers) controls some or all of the operations of the cluster tool and/or its separate modules. An example system controller is discussed further above in relation to FIG. 4B. It should be noted that the controller can be local to the cluster architecture, or can be located external to the cluster architecture in the manufacturing floor, or in a remote location and connected to the cluster architecture via a network. The system controller 550 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include one or more processing chambers for patterning, deposition and/or etch, and a controller including instructions for forming a negative pattern mask. One or more of the processing chambers may be configured to perform one or more of the treatment steps described herein. The instructions may include code for, in a relevant processing chamber or chambers, patterning a feature in a metal-oxide resist on a semiconductor substrate by dry deposition, treatment as described herein, EUV exposure to expose a surface of the substrate, dry developing the photopatterned resist, and/or etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network. A controller as described above with respect to FIG. 4B may be implemented with the tool in FIG. 5.

### Conclusion

Treatment strategies (e.g., post-application bake, post-exposure bake, post-application remote plasma treatment, and post-exposure remote plasma treatment) to enhance EUV-lithographic dry development performance of metal-containing EUV resist are disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

The following claims are provided for further illustration of certain embodiments of the disclosure. The disclosure is not necessarily limited to these embodiments.

1. A method of processing a substrate, comprising:
providing the substrate in a process chamber, wherein the substrate is a semiconductor substrate comprising a substrate layer and photoresist positioned over the substrate layer, and wherein the photoresist comprises metal; and
performing a treatment on the photoresist to modify material properties of the photoresist such that etch selectivity in a subsequent post-exposure dry development process is increased.

2. The method of claim 1, wherein the treatment results in increased cross-linking in the photoresist.

3. The method of claim 1, wherein the treatment involves a thermal process with control of temperature, pressure, ambient gas chemistry, gas flow/ratio, and moisture.

4. The method of claim 3, wherein the ambient gas chemistry comprises an inert gas selected from the group consisting of nitrogen (N₂), helium, neon, argon, xenon, and combinations thereof.

5. The method of claim 4, wherein the ambient gas chemistry is substantially free of reactive gases.

6. The method of claim 3, wherein the ambient gas chemistry comprises a reactive gas species.

7. The method of claim 6, wherein the reactive gas species is selected from the group consisting of water, hydrogen (H₂), oxygen (O₂), ozone, hydrogen peroxide, carbon monoxide, carbon dioxide, carbonyl sulfide, sulfur dioxide, chlorine (Cl₂), ammonia, nitrous oxide, nitric oxide, methane, an alcohol, acetyl acetone, formic acid, oxalyl chloride, pyridine, a carboxylic acid, an amine, and combinations thereof.

8. The method of claim 1, wherein the photoresist has been applied to the substrate layer but not yet exposed to patterning radiation, and the treatment is a post-application bake (PAB).

9. The method of claim 8, wherein the treatment increases an exposure radiation sensitivity of the photoresist to thereby achieve a lower dose to size while the substrate is exposed to the patterning radiation, and to achieve a lower line edge roughness after the substrate is exposed to the patterning radiation, as compared to a higher dose to size and a higher line edge roughness that would be achieved without the treatment.

10. The method of claim 8, wherein the treatment is conducted at a temperature between about 90 to 250° C. or 90 to 190° C.

11. The method of claim 1, wherein the photoresist has been patterned by partial exposure to patterning radiation resulting in exposed and unexposed portions of the photoresist, and the treatment is a post-exposure bake (PEB).

12. The method of claim 11, wherein the treatment is conducted at a temperature between about 170 to 250° C. or higher.

13. The method of claim 12, wherein a composition of both the unexposed and exposed portions of the photoresist is changed by the treatment to (i) increase an etch rate in a dry development etch gas, (ii) increase a difference in the composition between the unexposed and exposed portions of the photoresist, and/or (iii) increase a difference in one or more material properties between the unexposed and exposed portions of the photoresist.

14. The method of claim 1, wherein a temperature of the substrate is ramped while performing the treatment on the photoresist.

15. The method of claim 1, wherein the pressure during the treatment is controlled between about 0.1-760 Torr.

16. The method of claim 15, wherein the pressure during the treatment is controlled between about 0.1-10 Torr.

17. The method of claim 1, wherein the treatment involves exposing the photoresist to a remote plasma that generates radicals that react with the photoresist to modify one or more material properties of the photoresist.

18. The method of claim 17, wherein the radicals are generated from a gas species selected from the group consisting of water, hydrogen (H₂), oxygen (O₂), ozone, hydrogen peroxide, carbon monoxide, carbon dioxide, carbonyl sulfide, sulfur dioxide, chlorine (Cl₂), ammonia, nitrous oxide, nitric oxide, methane, an alcohol, acetyl acetone, formic acid, oxalyl chloride, pyridine, a carboxylic acid, an amine, and combinations thereof.

19. The method of claim 1, wherein the treatment is a thermal treatment performed using a first set of processing conditions and a second set of processing conditions, wherein the first and second sets of processing conditions vary with respect to at least one of ambient gases or mixtures, temperatures, and/or pressures to thereby modulate material properties of the photoresist and to tune etch selectivity of the photoresist.

20. The method of claim 1, wherein the photoresist is an EUV sensitive film.

21. The method of claim 1, wherein the treatment precedes exposing the photoresist to EUV lithography.

22. The method of claim 1, wherein the treatment occurs after exposing the photoresist to EUV lithography.

23. The method of claim 21, wherein the treatment is performed a second time after exposing the photoresist to EUV lithography.

24. An apparatus for processing a substrate, the apparatus comprising:
a process chamber comprising a substrate support;
a process gas source connected with the process chamber and associated gas flow-control hardware;
substrate thermal control apparatus;
substrate handling hardware connected with the process chamber; and
a controller having a processor, wherein the processor is at least operatively connected with the gas flow-control hardware, the substrate thermal control apparatus, and the substrate handling hardware, wherein the controller is configured to cause any one or more of the method of claim 1 or otherwise described herein.
